(19) United States
(12) Patent Application Publication
(10) Pub. No.: US 2012/0146183 A1
(43) Pub. Date: Jun. 14, 2012

(54) SEMICONDUCTOR DEVICE

(75) Inventors: Seung Jin LEE, Gyeonggi-do (KR); Byoung Hwa YOU, Gyeonggi-do (KR)

(73) Assignee: Hynix Semiconductor Inc., Icheon (KR)

(21) Appl. No.: 13/326,244

(22) Filed: Dec. 14, 2011

(30) Foreign Application Priority Data
Dec. 14, 2010 (KR) 10-2010-0127902

(51) Int. Cl. H01L 29/92

(52) U.S. Cl. 257/532; 257/E29.343

(57) ABSTRACT

A technology is a semiconductor device and a method of manufacturing the same, capable of preventing characteristics of a storage node from degrading to improve operation characteristics of a device, by connecting an upper electrode of a peripheral circuit area to an active region of the peripheral circuit area and thus making charges generated in a plasma environment to be transferred to the active regions of the peripheral circuit area. The method includes forming a landing contact plug on a semiconductor substrate in a cell area, forming a storage node contact plug connected to the landing contact plug and a dummy contact plug on the semiconductor substrate in a peripheral circuit area, forming a lower electrode connected to the storage node contact plug, and forming an upper electrode on the lower electrode and the dummy contact plug.

### CROSS-REFERENCES TO RELATED APPLICATION

The present application claims priority to Korean patent application number 10-2010-0127902 filed on 14 Dec. 2010, which is incorporated by reference in its entirety.

### BACKGROUND OF THE INVENTION

1. Technical Field

The present invention relates to a semiconductor device and a method of manufacturing the same, and more particularly, to a semiconductor device having a capacitor and a method of manufacturing the same.

2. Related Art

As the integration degree of semiconductor devices increases, device size becomes smaller and thus, the width of a capacitor, which stores data in a memory device such as a dynamic random access memory (DRAM), also becomes smaller. A capacitor has a structure in which a dielectric layer is interposed between a storage node and a plate node. Storage capacity (capacitance) of a capacitor having the above structure is proportional to the surface area of the storage node and is also proportional to a dielectric constant of the dielectric layer, but is inversely proportional to a gap between the storage node and the plate node, that is, the thickness of the dielectric layer.

To obtain a high capacitance capacitor, it is necessary to use a dielectric layer that has a large dielectric constant, increase the surface area of the node, or reduce the gap between the nodes. However, since there is a limit to reducing the gap between the nodes, that is, reducing the thickness of the dielectric layer, a method of using a dielectric layer having a high dielectric constant or increasing the surface area of the node has been studied to form a high capacitance capacitor. As a method of increasing the surface area of the node, a method of forming a capacitor in a cylinder type three-dimensional (3D) structure is typically used. As the height of a storage node having a cylinder type is increased, it is possible to obtain a larger surface area of the node.

### SUMMARY

The present invention is directed to providing a semiconductor device and a method of manufacturing the same, capable of preventing characteristics of a storage node from degrading and improving operation characteristics of a device, by coupling an upper electrode of a peripheral circuit area to an active region of the peripheral circuit area, thus allowing charges generated in a plasma environment to be transferred to the active region of the peripheral circuit area.

According to one aspect of an exemplary embodiment, a semiconductor device includes a landing contact plug formed on a semiconductor substrate in a cell area, a storage node contact plug disposed on the landing contact plug, a dummy contact plug formed on the semiconductor substrate in a peripheral circuit area, a lower electrode disposed on the storage node contact plug, and an upper electrode formed on the semiconductor substrate including the lower electrode and connected to the dummy contact plug in the peripheral circuit area.

The landing contact plug and the storage node contact plug may include polysilicon, respectively. The dummy contact plug may include polysilicon. The dummy contact plug may have the same depth as a stacking depth of the landing contact plug and the storage node contact plug.

The lower electrode may include a material selected from the group consisting of titanium nitride (TiN), ruthenium (Ru), ruthenium oxide (RuO₂), tantalum nitride (TaN), tungsten (W), tungsten nitride (WN), iridium (Ir), iridium oxide (IrO₂), platinum (Pt) and a combination thereof. The semiconductor device may further include a dielectric layer on a surface of the lower electrode. The dielectric layer may include a material selected from the group consisting of aluminum oxide (Al₂O₃), hafnium oxide (HfO₂), zirconium oxide (ZrO₂), tantalum oxide (Ta₂O₅) and a combination thereof.

The upper electrode may include a material selected from the group consisting of TiN, WN, W, Ru, silicon (Si) and a combination thereof. The semiconductor device may further include a metal contact plug connected to the upper electrode in the peripheral circuit area.

According to another aspect of an exemplary embodiment, a method of manufacturing a semiconductor device may include forming a landing contact plug on a semiconductor substrate in a cell area, forming a storage node contact plug connected to the landing contact plug and a dummy contact plug on the semiconductor substrate of a peripheral circuit area, forming a lower electrode connected to the storage node contact plug, and forming an upper electrode on the lower electrode and the dummy contact plug.

The forming the landing contact plug may include forming a first interlayer insulating layer on the semiconductor substrate including a gate and etching the first interlayer insulating layer in the cell area, and filling a conductive material within an etched portion of the first interlayer insulating layer, thereby forming the landing contact plug.

The forming the storage node contact plug and the dummy contact plug may include forming a second interlayer insulating layer and an etch stop layer on the landing contact plug and the first interlayer insulating layer, etching the etch stop layer and the second interlayer insulating layer in the cell area to form a storage node contact hole exposing the landing contact plug and etching the second and first interlayer insulating layers in the peripheral circuit area to form a dummy contact hole, and filling a conductive material within the storage node contact hole and the dummy contact hole, thereby forming the storage node contact plug and the dummy contact plug, respectively.

The forming the upper electrode may include forming the upper electrode on the etch stop layer including the lower electrode in the cell area and the dummy contact plug in the peripheral circuit area.

The landing contact plug, the storage node contact plug and the dummy contact plug may be formed of a material including polysilicon, respectively.

The forming the lower electrode may include forming the lower electrode using a material selected from the group consisting of TiN, Ru, RuO₂, TaN, W, WN, Ir, IrO₂, Pt and a combination thereof.

The method may further include, after the forming the lower electrode, forming a dielectric layer on a surface of the lower electrode. The forming the dielectric layer may include using a material selected from the group consisting of Al₂O₃, HfO₂, ZrO₂, Ta₂O₅ and a combination thereof.

The forming the upper electrode may include using a material selected from the group consisting of TiN, WN, W, Ru, Si and a combination thereof.

The method may further include, after the forming the upper electrode, forming a metal contact plug connected to the dummy contact plug.

According to another aspect of an exemplary embodiment, a method of manufacturing a semiconductor device includes forming a first interlayer insulating layer on a semiconductor substrate including a gate, etching the first interlayer insulating layer to form a landing plug contact hole exposing the semiconductor substrate in a cell area and a first dummy contact hole exposing the semiconductor substrate in a peripheral circuit area, filling the landing plug contact hole and the first dummy contact hole with a conductive material, thereby forming a landing contact plug and a first dummy contact plug, forming a second interlayer insulating layer and an etch stop layer on the first interlayer insulating layer including the landing contact plug and the first dummy contact plug, etching the etch stop layer and the second interlayer insulating layer to form a storage node contact hole exposing the landing contact plug in the cell area and a second dummy contact hole exposing the first dummy contact plug in the peripheral circuit area, filling a conductive material within the storage node contact hole and the second dummy contact hole to form a storage node contact plug in the cell area and a second dummy contact plug in the peripheral circuit area, forming a lower electrode connected to the storage node contact plug in the cell area, and forming an upper electrode on the etch stop layer including the lower electrode in the cell area and the second dummy contact plug in the peripheral circuit area.

The forming the landing contact plug, the storage node contact plug, the first dummy contact plug, and the second dummy contact plug may include forming the landing contact plug, the storage node contact plug, the first dummy contact plug, and the second dummy contact plug using a material including polysilicon, respectively. The forming the lower electrode may include using a material selected from the group consisting of TiN, Ru, RuO₂, TaN, W, WN, Ir, IrO₂, Pt and a combination thereof.

The method may further include, after the forming the lower electrode, forming a dielectric layer on a surface of the lower electrode. The forming the dielectric layer may include using a material selected from the group consisting of Al₂O₃, HfO₂, ZrO₂, Ta₂O₅ and a combination thereof.

The forming the upper electrode may include using a material including a material selected from the group consisting of TiN, WN, W, Ru, Si and a combination thereof.

The method may further include, after the forming the upper electrode, forming a metal contact plug connected to the second dummy contact plug.

These and other features, aspects, and embodiments are described below in the section entitled “DESCRIPTION OF EXEMPLARY EMBODIMENT.”

### BRIEF DESCRIPTION OF THE DRAWINGS

The above and other aspects, features, and other advantages of the subject matter of the present disclosure will be more clearly understood from the following detailed description taken in conjunction with the accompanying drawings, in which:

FIG. 1 is a cross-sectional view of a semiconductor device in the related art;

FIG. 2 is a cross-sectional view illustrating a semiconductor device according to an exemplary embodiment of the present invention;

FIGS. 3A to 3E are cross-sectional views illustrating a method of manufacturing a semiconductor device according to an exemplary embodiment of the present invention; and

FIGS. 4A to 4D are cross-sectional views illustrating a method of manufacturing a semiconductor device according to another exemplary embodiment of the present invention.

### DESCRIPTION OF EXEMPLARY EMBODIMENT

Exemplary embodiments are described herein with reference to cross-sectional illustrations that are schematic illustrations of exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein, but may include deviations in shapes that result, for example, from manufacturing. In the drawings, lengths and sizes of layers and regions may be exaggerated for clarity. Like reference numerals in the drawings denote like elements. It is also understood that when a layer is referred to as being “on” another layer or substrate, it can be directly on the other layer or substrate, or intervening layers may also be present.

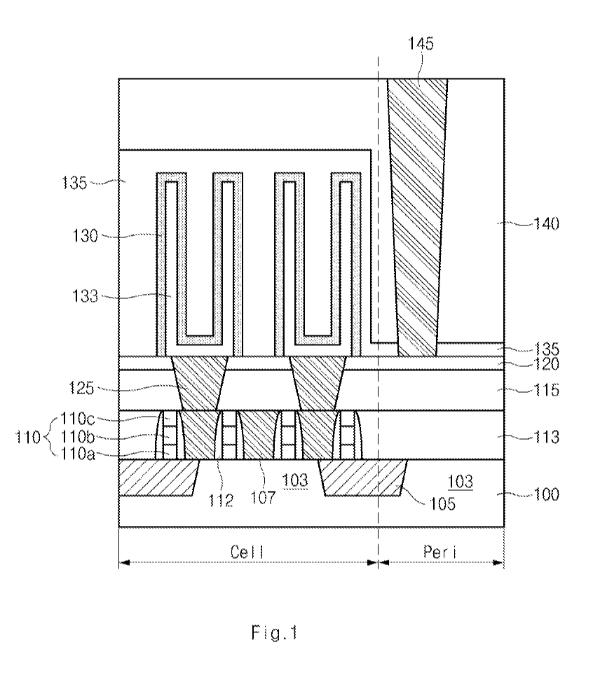

Hereinafter, a conventional cylinder type storage node will be described with reference to FIG. 1.

First, an active region 103 and a device isolation layer 105 are formed in a semiconductor device, including a cell area (Cell) and a peripheral circuit area (Peri). A gate 110, including a stacking structure of a gate polysilicon layer 110a, a gate metal layer 110b, and a gate hard mask layer 110c, is formed on the semiconductor substrate 100 in the cell area. A spacer 112 is formed on sidewalls of the gate 110.

A first interlayer insulating layer 113 is formed on the semiconductor substrate 100 including the gate 110. The first interlayer insulating layer 113 is etched to form a landing contact plug hole. A conductive material fills in the landing contact plug hole to form a landing contact plug 107.

Next, a second interlayer insulating layer 115 and an etch stop layer 120 are formed over the gate 110, the landing contact plug 107, and the first interlayer insulating layer 113. The etch stop layer 120 and the second interlayer insulating layer 115 are etched to form a storage node contact hole. Subsequently, a conductive material fills in the storage node contact hole to form a storage node contact plug 125. Next, a cylinder type lower electrode 133 is formed on the storage node contact plug 125 and a dielectric layer 130 is formed on a surface of the lower electrode 133. Hereafter, an upper electrode 135 is formed on the dielectric layer 130. In the peripheral circuit area, since the lower electrode 133 and the dielectric layer 130 are not formed, the upper electrode 135 is formed on the etch stop layer 120.

Next, a third interlayer insulating layer 140 is formed on the upper electrode 135. Then, the upper electrode 135 and the third interlayer insulating layer 140 in the peripheral circuit area are etched to form a metal contact hole. Subsequently, a metal layer fills in the metal contact hole to form a metal contact plug 145.

In a semiconductor device according to the above-described related art, since the upper electrode 135 formed in the peripheral circuit area is formed on the etch stop layer 120, the upper electrode 135 is floating. After the upper electrode 135 is formed, a metal contact is formed. An etching process for forming the metal contact hole is performed in a plasma environment. Noise generated in the process, in particular, charges generated in the plasma environment, move to the storage node (that is, the lower electrode) in the cell area and are trapped in the dielectric layer 130 of the storage node. Thus, the dielectric layer 130 is damaged and cannot properly function so that storage characteristics of the storage node are degraded, resulting in degraded operation characteristics of the semiconductor device.

Hereinafter, a semiconductor device and a method of manufacturing the same according to an exemplary embodiment of the present invention will be described in more detail with reference to the accompanying drawings.

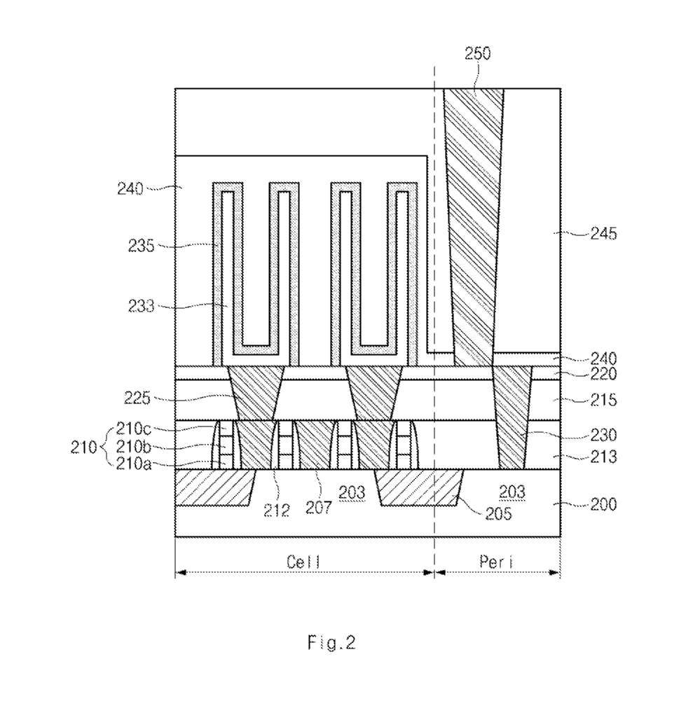

FIG. 2 is a cross-sectional view of a semiconductor device according to an exemplary embodiment. FIG. 2 illustrates a cell area (Cell) and a peripheral circuit area (Peri). First, as shown in FIG. 2, a gate 210 and a landing contact plug 207 are formed within a first interlayer insulating layer 213 over a semiconductor substrate 200 including an active region 203 and a device isolation layer 205 in the cell area. The gate 210 includes a gate polysilicon layer 210a, a gate metal layer 210b, and a gate hard mask layer 210c. A gate spacer 212 is formed over sidewalls of the gate 210. A storage node contact plug 225, which is coupled to the landing contact plug 207, is disposed in a second interlayer insulating layer 215 and an etch stop layer 220 and over the landing contact plug 207. The landing contact plug 207 and the storage node contact plug 225 may each include polysilicon.

A cylinder type lower electrode 233 is disposed over the storage node contact plug 225 and a dielectric layer 235 is disposed over a surface of the lower electrode 233. An upper electrode 240 is disposed over the dielectric layer 235. The lower electrode 233 may include any of titanium nitride (TiN), ruthenium (Ru), ruthenium oxide (RuO₂), tantalum nitride (TaN), tungsten (W), tungsten nitride (WN), iridium (Ir), iridium oxide (IrO₂), platinum (Pt), and a combination thereof. The dielectric layer 235 may include any of aluminum oxide (Al₂O₃), hafnium oxide (HfO₂), zirconium oxide (ZrO₂), tantalum oxide (Ta₂O₅), and a combination thereof. The upper electrode 240 may include any of TiN, WN, W, Ru, silicon, and a combination thereof. In an embodiment, the upper electrode 240 in the cell area is formed to have a height sufficient to cover the lower electrode 233 and the dielectric layer 235. The upper electrode 240 is formed to a smaller height over a surface of the etch stop layer 220 in the peripheral circuit area.

A third interlayer insulating layer 245 is disposed over the upper electrode 240 and a metal contact plug 250 is disposed in the third interlayer insulating layer 245 and the etch stop layer 220. In an embodiment, since the upper electrode 240 in the peripheral circuit area is floating, the dummy contact plug 230 is included to couple the upper electrode 240 and the active region 203 in the peripheral circuit area. In an embodiment, the dummy contact plug 230 is disposed in the first interlayer insulating layer 213, the second interlayer insulating layer 215, and the etch stop layer 220.

As described above, the dummy contact plug 230 is formed to connect the upper electrode 240 and the active region 203 in the peripheral circuit area so that charges generated in the plasma environment in an etching process for forming the metal contact hole, which will be performed later, are transferred not to the dielectric layer 235 in the cell area, but to the active region 203 in the peripheral circuit area, thereby preventing degradation of storage node characteristics.

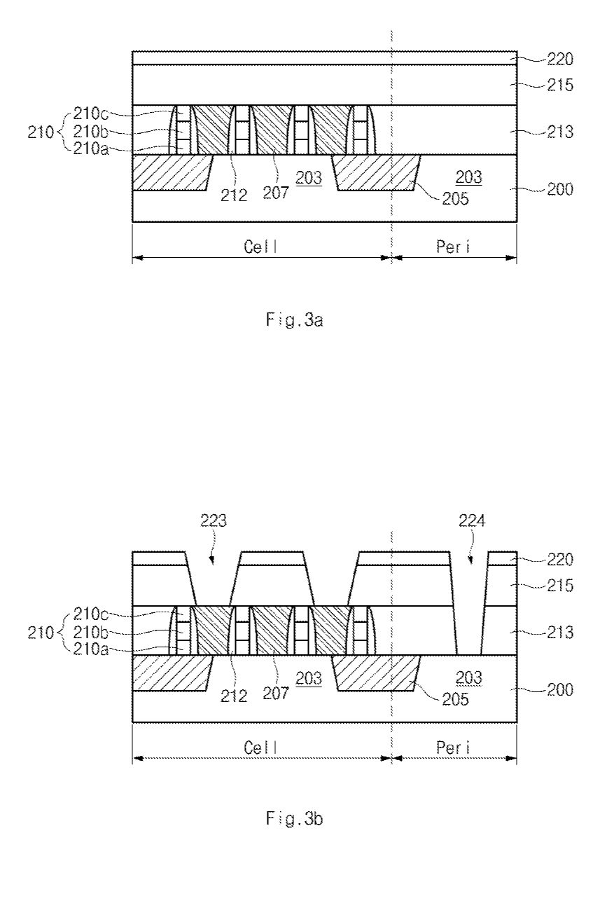

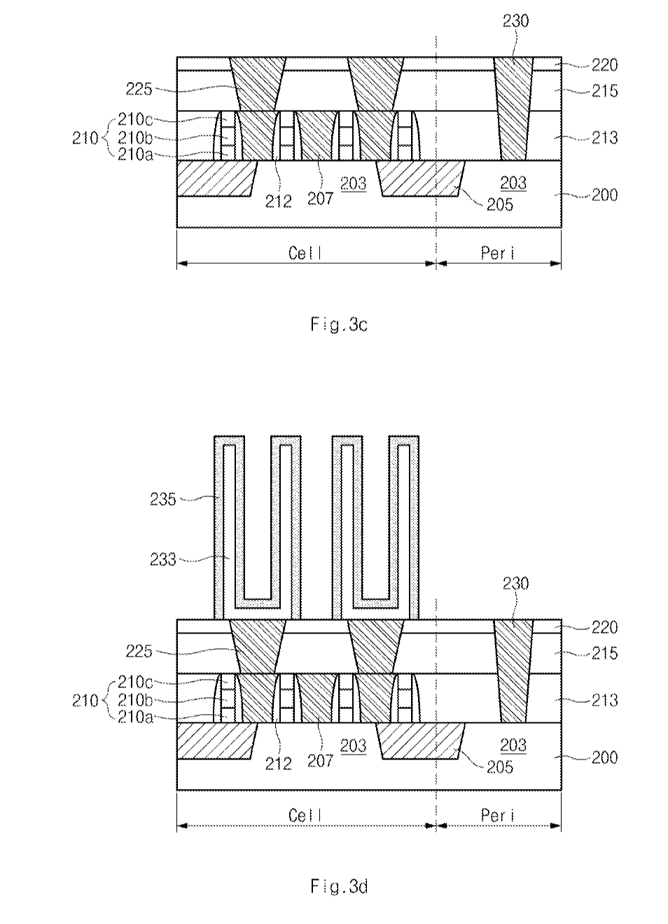

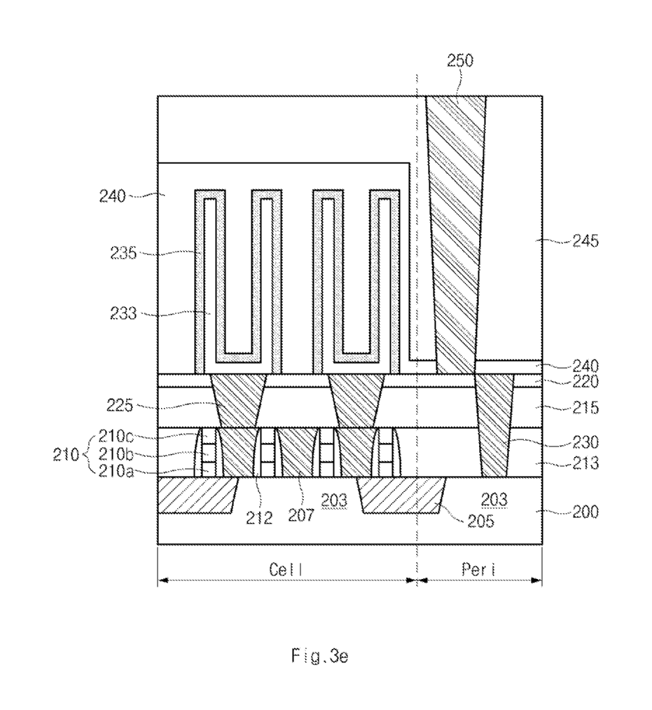

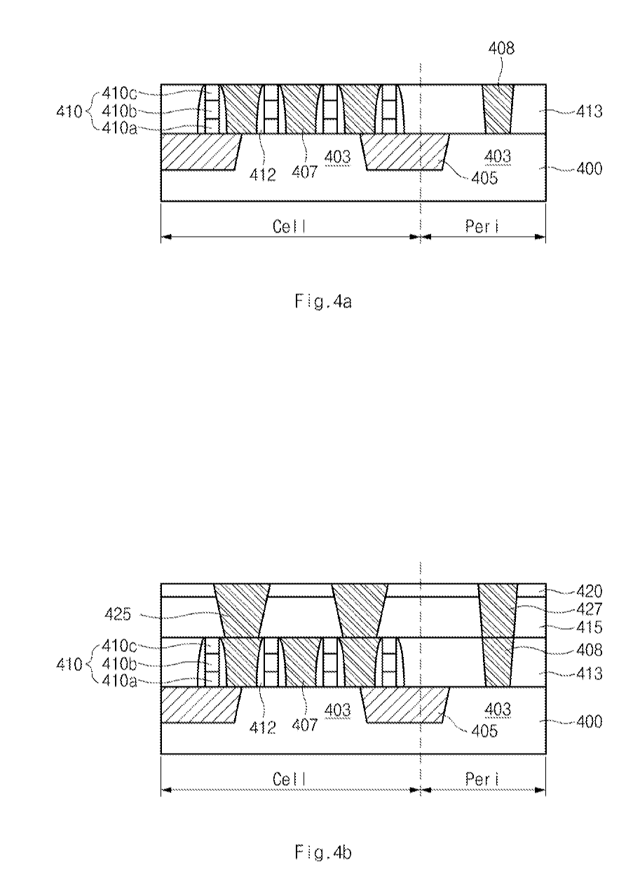

FIGS. 3A to 3E are cross-sectional views illustrating a method for forming a semiconductor device according to an exemplary embodiment of the present invention. FIGS. 3A to 3E illustrate a cell area (Cell) in which elements for storing data are formed and a peripheral area (Peri) including a peripheral circuit. The peripheral area is disposed adjacent to the cell area.

First, referring to FIG. 3A, a semiconductor substrate 200 is etched to form a trench for device isolation and an insulating layer fills in the trench to form a device isolation layer 205 defining an active region 203. Next, a gate 210 is formed over the semiconductor device 200, including the active region 203 and the device isolation layer 205 in a cell area, and a spacer 212 is formed over sidewalls of the gate 210. In an embodiment, the gate 210 includes a gate polysilicon layer 210a, a gate metal layer 210b, and a gate hard mask layer 210c. The spacer 212 includes a nitride layer.

Next, a first interlayer insulating layer 213 is formed over the semiconductor substrate 200 including the gate 210. The first interlayer insulating layer 213 in the cell area is etched to form a landing plug contact hole. A conductive material fills in the landing plug contact hole and a planarization process is performed until an upper surface of the gate 210 is exposed, thereby forming a landing contact plug 207. In an embodiment, the conductive material may include polysilicon. Subsequently, a second interlayer insulating layer 215 and an etch stop layer 220 are formed over the first interlayer insulating layer 213 including the landing contact plug 207. The second interlayer insulating layer 215 includes an oxide layer and the etch stop layer 220 includes a nitride layer.

Referring to FIG. 3B, the etch stop layer 220 and the second interlayer insulating layer 215 in the cell area are etched to form a storage node contact hole 223 exposing the landing contact plug 207. At the same time, the etch stop layer 220, the second interlayer insulating layer 215, and the first interlayer insulating layer 213 in the peripheral circuit area are also etched to form a dummy contact hole 224 exposing the active region 203. In an embodiment, the dummy contact hole 224 formed in the peripheral circuit area is formed to be deeper than the storage node contact hole 223 formed in the cell area. Since an etch rate is reduced in the cell area by the landing contact plug 207, the first interlayer insulating layer 213 and the second interlayer insulating layer 215 are completely etched in the peripheral circuit area, while the second interlayer insulating layer 215 is etched in the cell area.

Referring to FIG. 3C, a conductive material is formed over the etch stop layer 220, including the storage node contact hole 223 and the dummy contact hole 224, and a planarization process is performed until the etch stop layer 220 is exposed, thereby forming a storage node contact plug 225 and a dummy contact plug 230. The conductive material filling the storage node contact hole 223 and the dummy contact hole 224 may include polysilicon.

Referring to FIG. 3D, a sacrificial pattern (not shown) defining a storage node region of the cell area is formed over the etch stop layer 220 including the storage node contact plug 225 and the dummy contact plug 230. The sacrificial pattern may be formed of a material including any of a PSG layer, a PE-TEOS layer and a combination thereof. The sacrificial pattern is formed to expose the storage node contact plug 225 in the cell area. Further, the sacrificial pattern is formed of a material including an oxide layer and is formed to be thick enough to ensure sufficient capacitance of a capacitor. Next, a conductive material for a lower electrode is formed over an entire surface of the semiconductor substrate 200 including the sacrificial pattern. The conductive material for a lower electrode is formed by a chemical vapor deposition (CVD) method or an atomic layer deposition (ALD). The conductive material for a lower electrode includes any of TiN, Ru, RuO₂, TaN, W, WN, Ir, IrO₂, Pt, and a combination thereof.

A planarization process is performed until an upper surface of the sacrificial pattern is exposed, thereby forming separated cylinder type lower electrodes 233. Each of the lower electrodes 233 is formed to be connected to the storage node contact plug 225. A dip-out process is performed to remove the sacrificial pattern. Next, a dielectric layer 235 is conformally deposited over the lower electrode 233. The dielectric layer 235 is formed of any of Al₂O₃, HfO₂, ZrO₂, Ta₂O₅, and a combination thereof.

Referring to FIG. 3E, an upper electrode 240 is formed over the dielectric layer 235 in the cell area and over the etch stop layer 220 in the peripheral circuit area. The upper electrode 240 is referred to as a plate node. The upper electrode 240 is formed of of TiN, WN, W, Ru, silicon (Si), and a combination thereof. The upper electrode 240 is formed to such a thickness that it completely covers the lower electrode 233 in the cell area and completely fills in an inside of the cylinder type lower electrode 233. Since the lower electrode 233 and the dielectric layer 235 are not formed in the peripheral circuit area, and the upper electrode 240 is uniformly formed over the etch stop layer 220 in the peripheral circuit area, the upper electrode 240 formed in the cell area is thicker than the upper electrode 240 formed in the peripheral circuit area.

Hereinafter, a third interlayer insulating layer 245 is formed over the upper electrode 240. The third interlayer insulating layer 245 includes an oxide layer. The third interlayer insulating layer 245 and the upper electrode 240 in the peripheral circuit area are etched to form a metal contact hole. An etching process for forming the metal contact hole is performed until the etch stop layer 220 is exposed. Subsequently, a conductive material fills in the metal contact hole to form a metal contact plug 250. The conductive material filling in the metal contact hole may include polysilicon.

As shown in FIGS. 3A to 3E described above, the dummy contact plug 230 is formed below the upper electrode 240 in the peripheral circuit area so that the dummy contact plug 230 connects the upper electrode 240 to the active region 203, thereby preventing the upper electrode from floating in the peripheral circuit area. Accordingly, charges that can be generated by plasma in the metal contact etching process, performed in a later process, are transferred not to the cell area, but to the active region 203 of a junction diode unit in the peripheral circuit area. Thus, the dielectric layer 235 experiences no deterioration due to the charges and can function properly. That is, characteristic degradation of the storage node can be prevented and characteristics of the device can be improved.

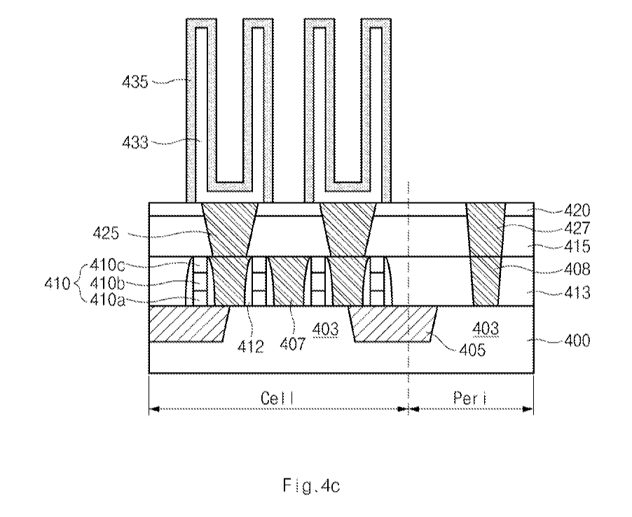

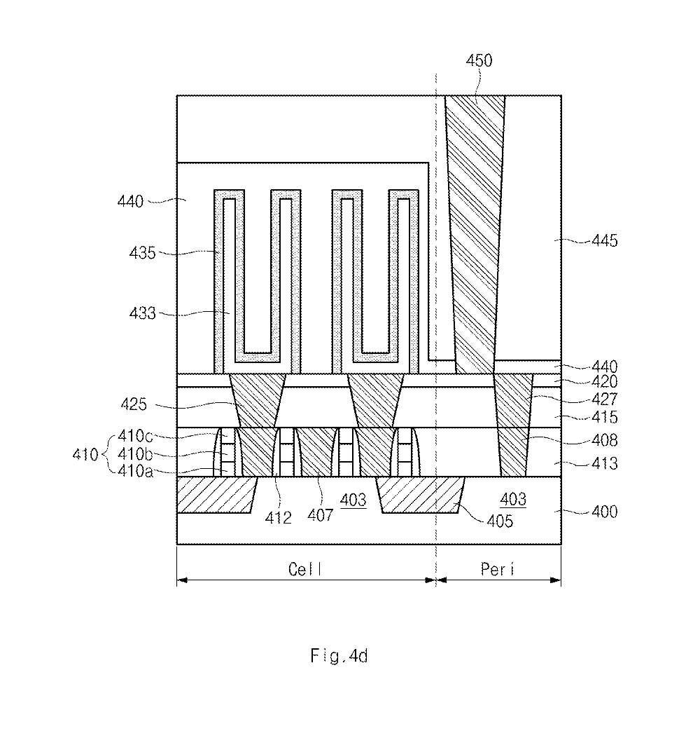

FIGS. 4A to 4D are cross-sectional views illustrating a method of manufacturing a semiconductor device according to another exemplary embodiment of the present invention.

Referring to FIG. 4A, an active region 403 and a device isolation layer 405 are formed in a semiconductor substrate 400 including a cell area (Cell) and a peripheral circuit area (Peri). Subsequently, a gate 410 is formed over the semiconductor substrate 400 in the cell area and a spacer 412 is formed over sidewalls of the gate 410. In an embodiment, the gate 410 includes a gate polysilicon layer 410a, a gate metal layer 410b, and a gate hard mask layer 410c. Here, the process of forming the active region 403, the device isolation layer 405 and the gate 410 is the same as the process described in FIG. 3A and thus, its description will be omitted.

A first interlayer insulating layer 413 is formed over the semiconductor substrate 400 including the gate 410. The first interlayer insulating layer 413 in the cell area is etched to form a landing plug contact hole exposing the semiconductor substrate 400. While the landing plug contact hole is formed, the first interlayer insulating layer 413 in the peripheral circuit area is also etched to form a first dummy contact hole exposing the active region 403. Subsequently, a conductive material fills in the landing plug contact hole in the cell area and the first dummy contact hole in the peripheral circuit area to form a landing contact plug 407 and a first dummy contact plug 408, respectively.

Referring to FIG. 4B, an etch stop layer 420 and a second interlayer insulating layer 415 are formed over the first interlayer insulating layer 413 including the gate 410, the landing contact plug 407 and the first dummy contact plug 408. The second interlayer insulating layer 415 includes an oxide layer and the etch stop layer includes a nitride layer. Then, the etch stop layer 420 and the second interlayer insulating layer 415 in the cell area are etched to form a storage node contact hole exposing the landing contact plug 407. At the same time, the etch stop layer 420 and the second interlayer insulating layer 415 in the peripheral circuit area are also etched to form a second dummy contact hole exposing the first dummy contact plug 408. Subsequently, a conductive material fills in the storage node contact hole and the second dummy contact hole to form a storage node contact plug 425 and a second dummy contact plug 427.

Referring to FIGS. 4C and 4D, a lower electrode 433, a dielectric layer 435 and an upper electrode 440 are formed. A third interlayer insulating layer 445 is formed over the upper electrode 440. Next, the third interlayer insulating layer 445 and the upper electrode 440 in the peripheral circuit area are etched to form a metal contact hole and a conductive material fills in the metal contact hole to form a metal contact plug 450. The processes of FIGS. 4C and 4D are the same as those of FIGS. 3E and 3F and thus, a detailed description will be omitted.

As described above, the first dummy contact plug 408 and the second dummy contact plug 427 are formed below the upper electrode 440 in the peripheral circuit area so that the first and second dummy contact plugs 408 and 427 connect the upper electrode 440 to the active region 403, thereby preventing the upper electrode 440 from floating. Accordingly, charges generated by plasma in the metal contact hole etching process that will be performed later are transferred, not to the cell area, but to the active region of the peripheral circuit area, so that deterioration of the dielectric layer 435 in the cell area can be prevented. That is, degradation of characteristics of the storage node can be prevented to improve characteristics of the device.

The above embodiments of the present invention are illustrative and not limitative. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

1. A semiconductor device, comprising:
a landing contact plug formed over a semiconductor substrate in a cell area;
a storage node contact plug disposed over the landing contact plug;
a dummy contact plug formed over the semiconductor substrate in a peripheral circuit area;
a lower electrode disposed over the storage node contact plug; and
an upper electrode formed over the semiconductor substrate including the lower electrode and coupled to the dummy contact plug in the peripheral circuit area.

2. The semiconductor device of claim 1, wherein the landing contact plug and the storage node contact plug each includes polysilicon.

3. The semiconductor device of claim 1, wherein the dummy contact plug includes polysilicon.

4. The semiconductor device of claim 1, wherein a top of the dummy contact plug is formed to be substantially level to a top of the storage node contact plug.

5. The semiconductor device of claim 1, wherein the lower electrode includes a material selected from the group consisting of titanium nitride (TiN), ruthenium (Ru), ruthenium oxide (RuO2), tantalum nitride (TaN), tungsten (W), tungsten nitride (WN), iridium (Ir), iridium oxide (IrO2), platinum (Pt), and a combination thereof.

6. The semiconductor device of claim 1, the device further comprising a dielectric layer disposed between the lower electrode and the upper electrode,
wherein the dielectric layer includes a material selected from the group consisting of aluminum oxide (Al2O3), hafnium oxide (HfO2), zirconium oxide (ZrO2), tantalum oxide (Ta2O5), and a combination thereof.

7. The semiconductor device of claim 1, wherein the upper electrode includes a material selected from the group consisting of TiN, WN, W, Ru, silicon (Si), and a combination thereof.

8. The semiconductor device of claim 1, the device further comprising a metal contact plug configured to couple the upper electrode and the dummy contact plug to each other in the peripheral circuit area.

9-23. (canceled)

24. A semiconductor device, comprising:
a semiconductor substrate including a cell area and a peripheral area;
a storage node plug formed in the cell area;
a dummy contact plug formed in the peripheral area;
a lower electrode coupled to the storage node plug; and
an upper electrode coupled to the lower electrode in the cell area and to the dummy contact plug in the peripheral area.

25. The semiconductor device of claim 24, wherein a top of the dummy contact plug is formed to be substantially flushed to a top of the storage node plug.

26. The semiconductor device of claim 24, wherein the storage node plug includes a first storage node plug coupled to the substrate in the cell area, and a second storage node plug coupled to the first storage node plug.

27. The semiconductor device of claim 26, wherein a top of the dummy contact plug is formed to be substantially flushed to a top of the second storage node plug.

28. The semiconductor device of claim 26, wherein the dummy contact plug includes a first dummy contact plug coupled to the substrate in the peripheral area, and a second dummy contact plug coupled to the first dummy contact plug.

29. The semiconductor device of claim 28, wherein a top of the first dummy contact plug is formed to be substantially flushed to a top of the first storage node plug, and wherein a top of the second dummy contact plug is formed to be substantially flushed to a top of the second storage node plug.
